(19) United States
(12) Patent Application Publication
(10) Pub. No.: US 2026/0135536 A1
(43) Pub. Date: May 14, 2026

(54) FILTER DEVICE, ANTENNA DEVICE, AND ANTENNA MODULE

(71) Applicant: Murata Manufacturing Co., Ltd., Nagaokakyo-shi (JP)

(72) Inventor: Shinya TACHIBANA, Nagaokakyo-shi (JP)

(73) Assignee: Murata Manufacturing Co., Ltd., Nagaokakyo-shi (JP)

(21) Appl. No.: 19/445,620

(22) Filed: Jan. 12, 2026

Related U.S. Application Data
(63) Continuation of application No. PCT/JP2024/022810, filed on Jun. 24, 2024.

(30) Foreign Application Priority Data
Sep. 7, 2023 (JP) 2023-144923

(51) Int. Cl. H03H 7/01; H01Q 9/30; H01Q 21/28

(52) U.S. Cl. CPC H03H 7/0115; H01Q 9/30; H01Q 21/28

(57) ABSTRACT

A filter device includes an insulating body including a first outer electrode and a second outer electrode, a first inductor coupled to the first outer electrode, and a resonant circuit including a second inductor and a capacitor. The first inductor is coupled to the second outer electrode and to the resonant circuit. The first inductor and the second inductor are stacked in the insulating body. At least one of the first inductor and the second inductor includes a plurality of inductor patterns. The first inductor and the second inductor are alternately disposed in a stacking direction and are magnetically coupled.

### CROSS-REFERENCE TO RELATED APPLICATIONS

This application is a continuation of International Application No. PCT/JP 2024/022810, filed on Jun. 24, 2024, which claims the benefit of priority to Japanese Patent Application No. 2023-144923, filed on Sep. 7, 2023. The entire contents of each of these applications are incorporated herein by reference.

### TECHNICAL FIELD

The present disclosure relates to filter devices, antenna devices, and antenna modules.

### BACKGROUND ART

Filter devices that pass radio-frequency signals in a specific first frequency band while attenuating radio-frequency signals in a specific second frequency band are known. For example, International Publication No. 2023/080009 (Patent Document 1) discloses a filter device having a pass band of a first frequency band and an attenuation band of a second frequency band lower than the first frequency band.

### CITATION LIST

### Patent Document

Patent Document 1: International Publication No. 2023/080009

### SUMMARY

A filter device according to an aspect of the present disclosure includes an insulating body including a first outer electrode and a second outer electrode, a first inductor coupled to the first outer electrode, and a resonant circuit including a second inductor and a capacitor. The first inductor is coupled to the second outer electrode and to the resonant circuit. The first inductor and the second inductor are stacked in the insulating body. At least one of the first inductor and the second inductor includes a plurality of inductor patterns. The first inductor and the second inductor are alternately disposed in a stacking direction and are magnetically coupled.

An antenna device according to another aspect of the present disclosure includes a radiating element configured to emit a radio-frequency signal within the first frequency band as radio waves, a feed circuit configured to supply the radio-frequency signal within the first frequency band to the radiating element, and the filter device described above, provided between the radiating element and the feed circuit.

### BRIEF DESCRIPTION OF DRAWINGS

FIG. 1 illustrates a configuration of an antenna device according to a first embodiment.

FIG. 2 is a graph illustrating the frequency characteristic of reactance of a filter device according to the first embodiment.

FIG. 3 illustrates a configuration of an antenna module according to the first embodiment.

FIG. 4 is a basic circuit diagram of the filter device according to the first embodiment.

FIG. 5 is a detailed circuit diagram of the filter device according to the first embodiment.

FIG. 6 is an external view of the filter device according to the first embodiment.

FIG. 7 is a perspective view illustrating the stacked structure of the filter device according to the first embodiment.

FIG. 8 is an exploded plan view illustrating the stacked structure of the filter device according to the first embodiment.

FIG. 9 is an exploded plan view illustrating the stacked structure of the filter device according to the first embodiment.

FIG. 10 is an exploded plan view illustrating the stacked structure of the filter device according to the first embodiment.

FIG. 11 is a detailed circuit diagram illustrating the parasitic capacitance generated in the filter device according to the first embodiment.

FIG. 12 is a detailed circuit diagram illustrating the parasitic capacitance generated in the filter device according to the first embodiment.

FIG. 13 is a detailed circuit diagram illustrating the parasitic capacitance generated in the filter device according to the first embodiment.

FIG. 14 is a graph illustrating an example of insertion loss of the filter device according to the first embodiment.

FIG. 15 is a detailed circuit diagram of a filter device according to a second embodiment.

FIG. 16 is a perspective view illustrating the stacked structure of the filter device according to the second embodiment.

FIG. 17 is an exploded plan view illustrating the stacked structure of the filter device according to the second embodiment.

FIG. 18 is an exploded plan view illustrating the stacked structure of the filter device according to the second embodiment.

FIG. 19 is an exploded plan view illustrating the stacked structure of the filter device according to the second embodiment.

FIG. 20 is a graph illustrating an example of insertion loss of the filter device according to the second embodiment.

### DESCRIPTION OF EMBODIMENTS

Hereinafter, embodiments of the present disclosure will be described in detail with reference to the drawings. In the drawings, identical or equivalent parts are denoted by the same reference numerals, and descriptions thereof will not be reiterated.

The filter device disclosed in International Publication No. 2023/080009 includes a first inductor and a resonant circuit including a second inductor and a capacitor, coupled to the first inductor. When the first inductor and the second inductor are magnetically coupled, a mutual inductance is generated. Due to this mutual inductance, a parallel resonator is formed. As a result, the parallel resonance attenuates radio-frequency signals in the second frequency band, while the series resonance passes radio-frequency signals in the first frequency band.

The inventor has observed that such filter devices are required to effectively attenuate radio-frequency signals through parallel resonance while achieving further miniaturization. The present disclosure addresses these needs as described in the following embodiments.

The filter device of the present disclosure attenuates radio-frequency signals through parallel resonance by using mutual inductance that occurs in the path between the first inductor and the second outer electrode as a result of magnetic coupling between the first inductor and the second inductor.

Further, in the filter device, at least one of the first inductor and the second inductor includes multiple inductor patterns, and the first inductor and the second inductor are alternately disposed in the stacking direction and magnetically coupled. This configuration enables the filter device to maximize the coupling coefficient between the first inductor and the second inductor while achieving miniaturization, thereby effectively attenuating radio-frequency signals through parallel resonance. Accordingly, the present disclosure provides a filter device that is small in size and achieves favorable attenuation and bandpass characteristics.

The present disclosure has been made to address this and other problems, and is directed to providing a filter device that is small in size and achieves favorable attenuation and bandpass characteristics.

### First Embodiment

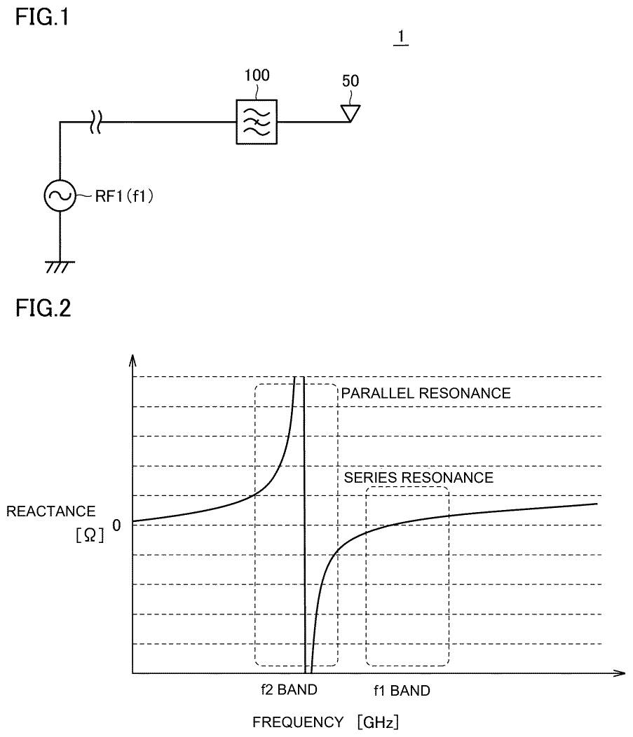

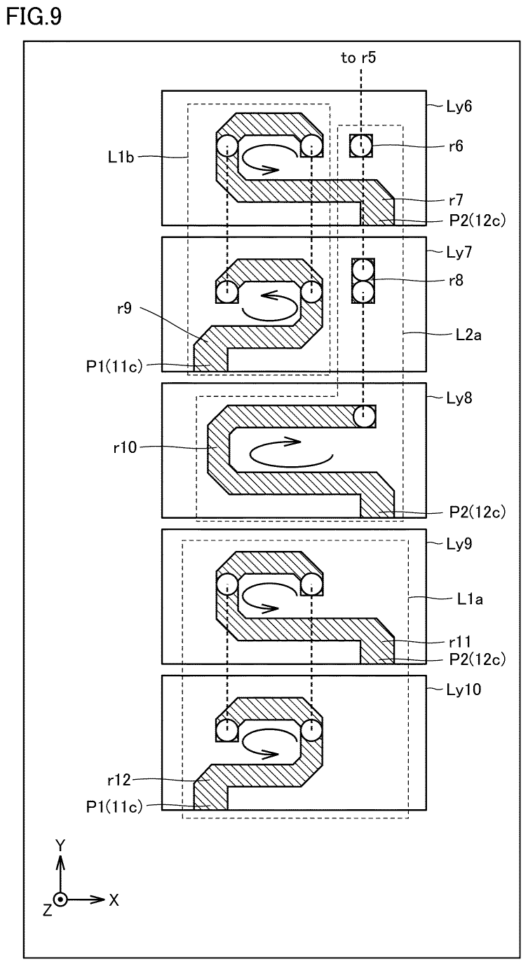

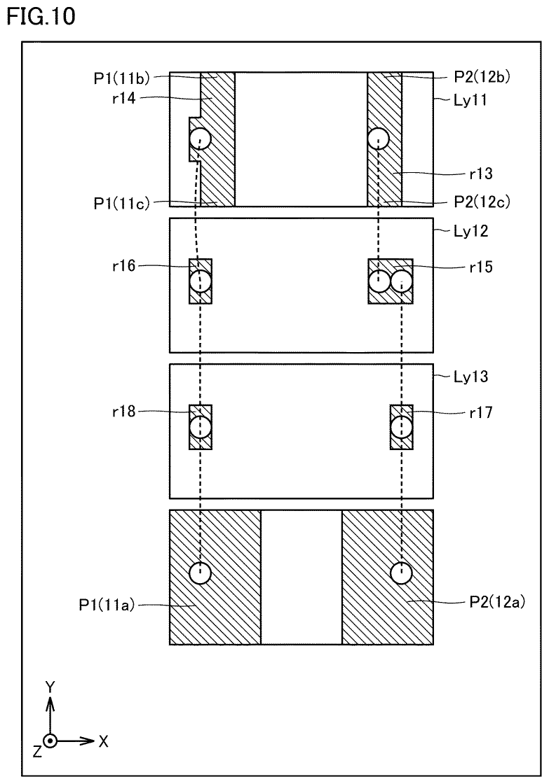

Referring to FIGS. 1 to 14, a filter device 100 according to a first embodiment will be described.

### Antenna Device Configuration

FIG. 1 illustrates a configuration of an antenna device 1 according to the first embodiment. The antenna device 1 may be installed in communication devices capable of transmitting and receiving radio waves, such as mobile terminals, for example, mobile phones, smartphones, tablet terminals, and smart watches, and personal computers (PCs) having communication functions.

As illustrated in FIG. 1, the antenna device 1, which is an example of a “first antenna device,” includes a feed circuit RF1, a radiating element 50, and the filter device 100. The feed circuit RF1 supplies radio-frequency signals in a specific first frequency band to the radiating element 50. In the first embodiment, the first frequency band is referred to as the f1 band. The radiating element 50 is, for example, a monopole antenna. The radiating element 50 emits radio-frequency signals within the f1 band, supplied from the feed circuit RF1, into the air as radio waves. The radiating element 50 is not necessarily a monopole antenna, but may be, for example, a dipole antenna, an inverted-F antenna, or a loop antenna.

The filter device 100 is provided between the radiating element 50 and the feed circuit RF1. The filter device 100 is configured to attenuate radio-frequency signals in a second frequency band while passing radio-frequency signals in the first frequency band (f1 band). In the first embodiment, the second frequency band is referred to as the f2 band. The f2 band is a frequency band that is lower than the first frequency band (f1 band) and is close to the f1band. For example, when the f1 band corresponds to the 5 GHz band (5.15-5.85 GHz), which is used for Wi-Fi (registered trademark), the f2 band corresponds to the n79 band (4.4-5.0 GHz). This filter device 100 is particularly useful when the antenna device 1 is used near antennas for transmitting and receiving radio waves in the f2 band.

FIG. 2 is a graph illustrating the frequency characteristic of reactance of the filter device 100 according to the first embodiment. In FIG. 2, the graph has the horizontal axis representing frequency and the vertical axis representing reactance, illustrating the frequency characteristic of reactance of the filter device 100. As illustrated in FIG. 2, in the filter device 100, the attenuation band resulting from parallel resonance corresponds to the f2 band, and the pass band resulting from series resonance corresponds to the f1 band.

### Antenna Module Configuration

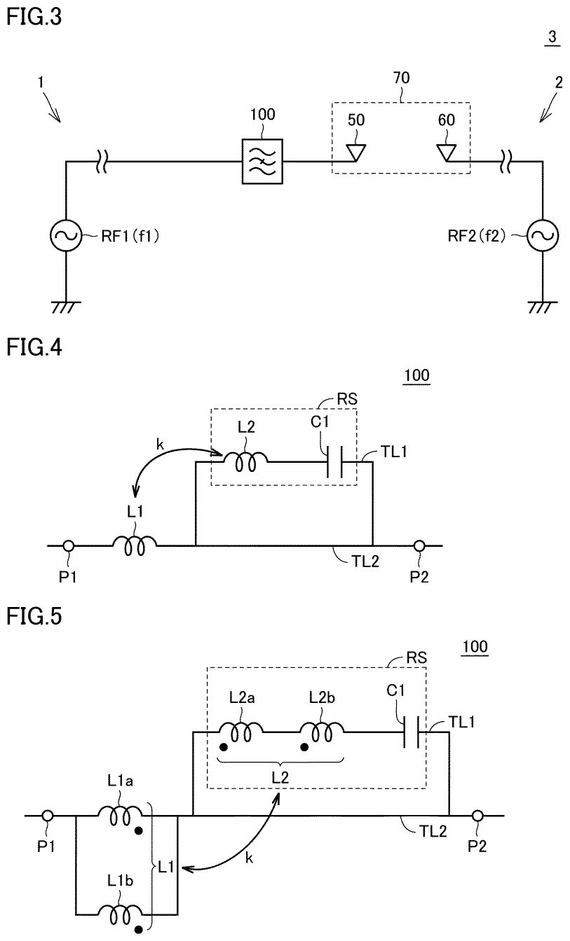

FIG. 3 illustrates a configuration of an antenna module 3 according to the first embodiment. The antenna module 3 may be installed in communication devices capable of transmitting and receiving radio waves, such as mobile terminals, for example, mobile phones, smartphones, tablet terminals, and smart watches, and PCs having communication functions.

As illustrated in FIG. 3, the antenna module 3 includes the antenna device 1 according to the first embodiment and an antenna device 2. The antenna device 2, which is an example of a “second antenna device”, includes a feed circuit RF2 and a radiating element 60. The feed circuit RF2 supplies radio-frequency signals in a specific second frequency band (f2 band) to the radiating element 60. The radiating element 60 is, for example, a monopole antenna. The radiating element 60 emits radio-frequency signals within the f2 band, supplied from the feed circuit RF2, into the air as radio waves. The radiating element 60 is not necessarily a monopole antenna, but may be, for example, a dipole antenna, an inverted-F antenna, or a loop antenna.

The radiating element 60 is provided on a substrate 70 having the radiating element 50 of the antenna device 1. In the example in FIG. 3, the radiating elements 50 and 60 are provided on the same substrate 70. However, the radiating elements 50 and 60 may be provided on separate substrates, provided that the radiating elements 50 and 60 are provided in the same antenna module 3.

The radio-frequency signals within the f2 band emitted from the antenna device 2 are absorbed by the antenna device 1 located near the antenna device 2. As a result, the radiation efficiency of the antenna device 2 is degraded. For this reason, the filter device 100 is configured to attenuate radio-frequency signals within the f2 band emitted from the antenna device 2. Specifically, the filter device 100 is configured to pass radio-frequency signals within the f1 band supplied from the feed circuit RF1 and supply the radio-frequency signals to the radiating element 50, while not passing radio-frequency signals within the f2 band emitted from the antenna device 2, thereby suppressing the degradation of the radiation efficiency of the antenna device 2. This configuration achieves miniaturization of the antenna module by positioning multiple antennas closer together while suppressing degradation of antenna characteristics.

### Filter Device Configuration

Referring to FIGS. 4 to 14, the filter device 100 according to the first embodiment will be described in detail. FIG. 4 is a basic circuit diagram of the filter device 100 according to the first embodiment. The filter device 100 is a trap filter that obstructs and attenuates the passage of radio-frequency signals in a specific frequency band (f2 band), or may be a band-elimination filter.

As illustrated in FIG. 4, the filter device 100 includes a first port P1, a second port P2, an inductor L1, and a resonant circuit RS including an inductor L2 and a capacitor C1. The filter device 100 can be coupled to the transmission line leading to the feed circuit RF1 through the first port P1. The filter device 100 can be coupled to the transmission line leading to the radiating element 50 through the second port P2.

When the radio-frequency signal supplied from the feed circuit RF1 is supplied to the radiating element 50 through the filter device 100, the first port P1 functions as an input port and the second port P2 functions as an output port. When the radio-frequency signal received by the radiating element 50 is supplied to the circuitry including the feed circuit RF1 through the filter device 100, the first port P1 functions as an output port and the second port P2 functions as an input port. In this example, the feed circuit RF1 is coupled to the first port P1, and the radiating element 50 is coupled to the second port P2. Conversely, the radiating element 50 may be coupled to the first port P1, and the feed circuit RF1 may be coupled to the second port P2. Both connections achieve the same effects.

The inductor L1 is an example of a “first inductor”. The inductor L2 is an example of a “second inductor”. One terminal of the inductor L1 is coupled to the first port P1. The other terminal of the inductor L1 is coupled to the second port P2 through a second path TL2, which is a short-circuited path, and also to the second port P2 via the resonant circuit RS provided in a first path TL1. As described above, the first path TL1 and the second path TL2, which are coupled in parallel, are provided between the inductor L1 and the second port P2, and the resonant circuit RS is provided in the first path TL1, and the second path TL2 is short-circuited.

The resonant circuit RS is a series resonator configured by coupling the inductor L2 and the capacitor C1 in series between the inductor L1 and the second port P2.

Between the first port P1 and the second port P2, the inductors L1 and L2 are coupled in series and are configured to be magnetically coupled to each other. As a result, a mutual inductance M can be generated between the inductors L1 and L2. Due to the generated mutual inductance M, mutual inductance affects the first path TL1 and the second path TL2 individually, thereby forming a parallel resonator. The polarity relationship between the inductors L1 and L2 may be subtractive polarity or may be additive polarity. When the inductors L1 and L2 are magnetically coupled with subtractive polarity (hereinafter also referred to as “subtractive coupling”), this magnetic coupling is such that magnetic fields are generated in directions in which the magnetic fluxes passing through the inductors L1 and L2 weaken each other. When the inductors L1 and L2 are magnetically coupled with additive polarity (hereinafter also referred to as “additive coupling”), this magnetic coupling is such that magnetic fields are generated in directions in which the magnetic fluxes passing through the inductors L1 and L2 strengthen each other.

For example, when the current flowing to the inductor pattern of the inductor L1 in the case where current flows from the first port P1 to the inductor L1 flows in the same direction as the current flowing to the inductor pattern of the inductor L2 in the case where current flows from the inductor L1 to the inductor L2, the inductors L1 and L2 are in additive coupling. When the inductors L1 and L2 are in additive coupling, a mutual inductance of +M appears in the first path TL1 and a mutual inductance of −M appears in the second path TL2.

Conversely, when the current flowing to the inductor pattern of the inductor L1 in the case where current flows from the first port P1 to the inductor L1 flows in a different direction from the current flowing to the inductor pattern of the inductor L2 in the case where current flows from the inductor L1 to the inductor L2, the inductors L1 and L2 are in subtractive coupling. When the inductors L1 and L2 are in subtractive coupling, a mutual inductance of −M appears in the first path TL1 and a mutual inductance of +M appears in the second path TL2.

The series resonant frequency f0 of the resonant circuit RS is expressed as f0=½π√(L2×C1). At the series resonant frequency f0, the total reactance X of the inductor L2 and the capacitor C1 is 0 (zero) (X=0). At this series resonant frequency f0, the filter device 100 operates as a parallel resonator formed by a mutual inductance of +M and a mutual inductance of −M. The resonant frequency of this parallel resonator coincides with the series resonant frequency f0 of the resonant circuit RS and serves as the parallel resonant frequency of the attenuation band (f2 band) of the filter device 100.

With the filter device 100 according to the first embodiment, designers can easily design the parallel resonant frequency of the attenuation band simply by selecting parameters such as the values of the inductor L2 and the capacitor C1 that constitute the resonant circuit RS. As such, the filter device 100 has an advantage in configuration design.

Additionally, designers can change the series resonant frequency of the pass band (f1 band) by changing the coupling coefficient k between the inductors L1 and L2, and can also bring the pass band (f1 band) formed by series resonance closer to the attenuation band (f2 band) formed by parallel resonance. This means that designers can configure the filter device 100 to have a narrow band in which the attenuation characteristic changes sharply near the parallel resonant frequency of the attenuation band (f2 band).

The coupling coefficient k between the inductors L1 and L2 also affects the attenuation level and attenuation band width of the radio-frequency signals in the attenuation band (f2 band). The larger the coupling coefficient k, the greater the mutual inductance generated becomes. As a result, radio-frequency signals are sharply attenuated in the attenuation band (f2 band), resulting in a favorable attenuation characteristic.

To increase the coupling coefficient k, one conceivable method is to increase the magnetic fluxes generated in the inductors L1 and L2 by increasing the inductance of the inductor L1 or L2 or bringing the inductors L1 and L2 closer together. However, since the inductor L1 affects the bandpass characteristic of radio-frequency signals in the pass band (f1 band), it is preferable to minimize the inductance of the inductor L1 to obtain a favorable bandpass characteristic without attenuating radio-frequency signals in the pass band (f1 band). Additionally, if the number of turns of the inductor L2 is increased or the opening area of the inductor L2 is widened to increase the inductance of the inductor L2, the entire filter device 100 becomes larger, which makes miniaturization of the filter device 100 difficult. Overall, it is difficult to increase the inductance of the inductor L1 or L2 while miniaturizing the filter device 100.

If the inductors L1 and L2 are positioned close to each other, parasitic capacitance may be generated between the inductors L1 and L2. Such parasitic capacitance may cause self-resonance in the inductor L1 or L2 and make it difficult to obtain favorable bandpass characteristics.

For these reasons, as will be described below, the filter device 100 according to the first embodiment is configured to effectively attenuate radio-frequency signals through parallel resonance to obtain favorable attenuation and bandpass characteristics, while achieving miniaturization.

FIG. 5 is a detailed circuit diagram of the filter device 100 according to the first embodiment. As illustrated in FIG. 5, the filter device 100 includes multiple inductors as the inductor L1. For example, the inductor L1 includes inductors L1a and L1b coupled in parallel between the first port P1 and the resonant circuit RS. The inductors L1a and L1b are examples of a “first sub-inductor.” The filter device 100 includes multiple inductors as the inductor L2. For example, the inductor L2 includes inductors L2a and L2b coupled in series between the inductor L1 and the second port P2. The inductors L2a and L2b are examples of a “second sub-inductor.”

One terminal of each of the inductors L1a and L1b coupled in parallel is coupled to the first port P1, and the other terminal of each of the inductors L1a and L1b is coupled to the inductor L2a. Of the inductors L2a and L2b coupled in series, the inductor L2a is coupled to the inductors L1a and L1b, while the inductor L2b is coupled to the capacitor C1. Specifically, the inductors L1a and L1b are coupled in series with the inductor L2a at a common potential. In the example in FIG. 5, the inductors L1 and L2 are in subtractive coupling, resulting in a coupling coefficient k.

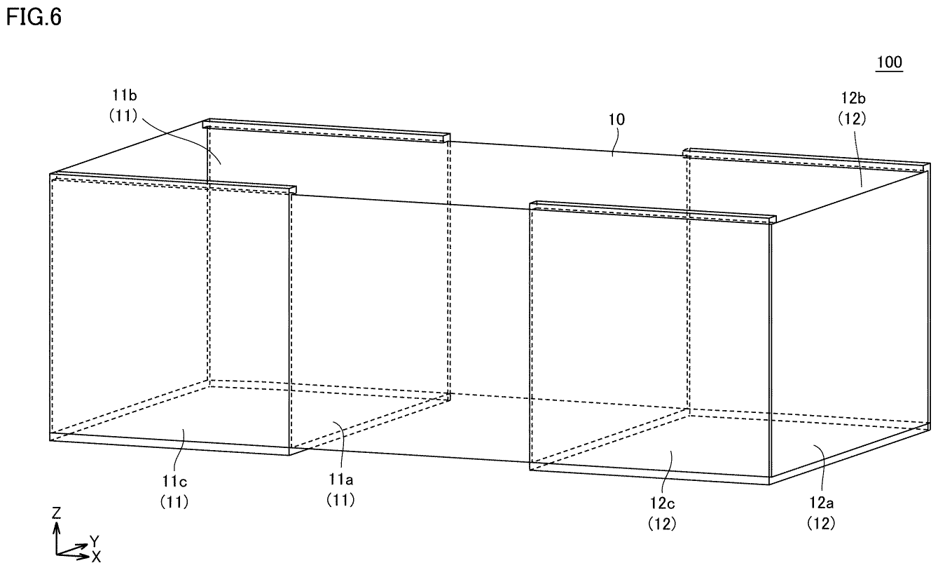

FIG. 6 is an external view of the filter device 100 according to the first embodiment. The filter device 100 is, for example, formed as an integrated chip component, with the inductors and the capacitor disposed within an insulating body 10 (enclosure) formed by stacking multiple dielectric layers. In FIG. 6, the length direction of the filter device 100 (the insulating body 10) is defined as the X direction, the width direction is defined as the Y direction, and the height direction is defined as the Z direction, where the stacking direction of the dielectric layers corresponds to the Z direction. The bottom surface (X-Y plane) of the filter device 100 serves as a mounting surface that is to be placed on a mounting substrate. When the filter device 100 is mounted on the mounting substrate, the bottom surface faces the mounting substrate.

As illustrated in FIG. 6, the filter device 100 includes a first outer electrode 11 and a second outer electrode 12 that are electrically coupled to inductor patterns or electrode patterns disposed inside the insulating body 10. The first outer electrode 11 corresponds to the first port P1 described above. The second outer electrode 12 corresponds to the second port P2 described above.

The first outer electrode 11 is U-shaped. The first outer electrode 11 includes an outer electrode 11a disposed on a bottom surface (X-Y plane) of the insulating body 10, an outer electrode 11b disposed on one side surface (X-Z plane) of the insulating body 10, and an outer electrode 11c disposed on another side surface (X-Z plane) of the insulating body 10. The outer electrode 11b faces the outer electrode 11c, and the ends of the outer electrodes 11b and 11c are connected to the ends of the outer electrode 11a.

The second outer electrode 12 is spaced apart by a certain distance from the first outer electrode 11 along the length direction (X direction) of the filter device 100 (the insulating body 10). The second outer electrode 12 is U-shaped. The second outer electrode 12 includes an outer electrode 12a disposed on a bottom surface (X-Y plane) of the insulating body 10, an outer electrode 12b disposed on one side surface (X-Z plane) of the insulating body 10, and an outer electrode 12c disposed on another side surface (X-Z plane) of the insulating body 10. The outer electrode 12b faces the outer electrode 12c, and the ends of the outer electrodes 12b and 12c are connected to the ends of the outer electrode 12a.

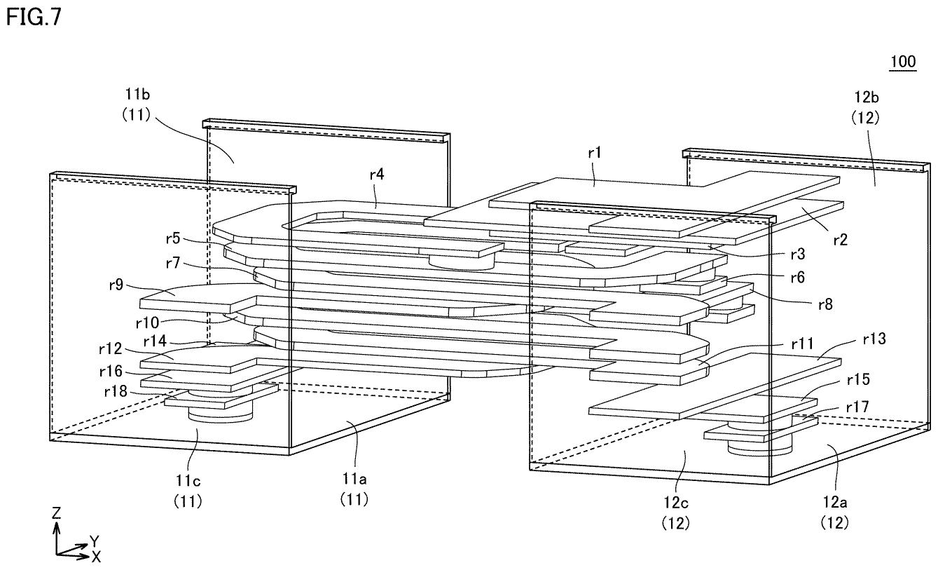

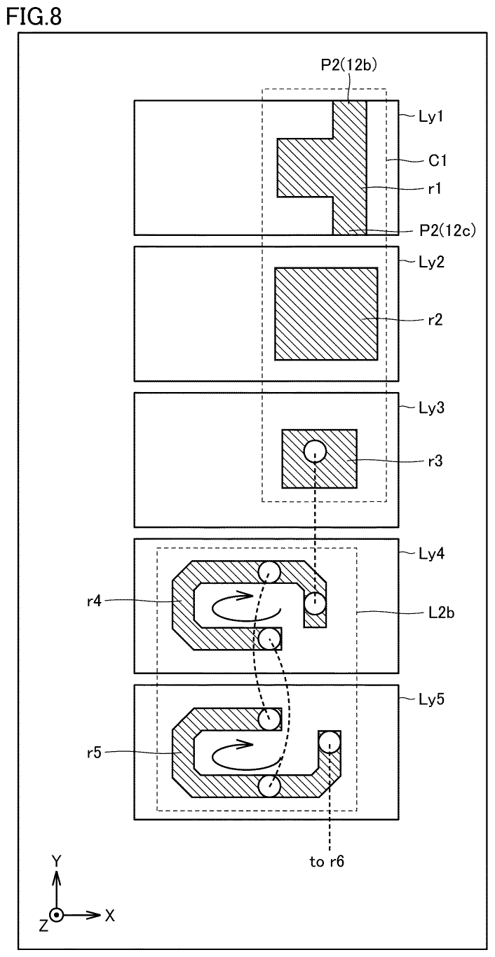

FIG. 7 is a perspective view illustrating the stacked structure of the filter device 100 according to the first embodiment. In FIG. 7, the outline of the insulating body 10 is omitted for ease of understanding the description of the filter device 100. FIGS. 8 to 10 provide exploded plan views illustrating the stacked structure of the filter device 100 according to the first embodiment.

As illustrated in FIGS. 7 to 10, the filter device 100 is formed by stacking multiple dielectric layers Ly1 to Ly13 in the stacking direction (Z direction) through a stacking process. The dielectric layers Ly1 to Ly13 are ceramic green sheets. The electrode patterns and inductor patterns are formed by applying a conductive paste (for example, Ni paste) using a screen-printing method.

The capacitor C1 is formed of electrode patterns r1 to r3 that are formed respectively in the dielectric layers Ly1 to Ly3.

The electrode pattern r1, forming a portion of the capacitor C1, is formed in the dielectric layer Ly1. One end of the electrode pattern r1 is electrically coupled to the second port P2 (the outer electrode 12b of the second outer electrode 12). The other end of the electrode pattern r1 is electrically coupled to the second port P2 (the outer electrode 12c of the second outer electrode 12).

The electrode pattern r2, forming a portion of the capacitor C1, is formed in the dielectric layer Ly2. The electrode pattern r2 is not electrically coupled to either the first port P1 or the second port P2, and the electrode pattern r2 is also not electrically coupled to other electrode patterns.

The electrode pattern r3, forming a portion of the capacitor C1, is formed in the dielectric layer Ly3. The electrode pattern r3 is electrically coupled to one end of the inductor pattern r4 in the dielectric layer Ly4 through a via-conductor.

As described above, the capacitor C1 is structured by using the space defined between the electrode pattern r1 formed in the dielectric layer Ly1 and the electrode pattern r2 formed in the dielectric layer Ly2 and the space defined between the electrode pattern r2 formed in the dielectric layer Ly2 and the electrode pattern r3 formed in the dielectric layer Ly3.

The inductor L2b is formed of inductor patterns r4 and r5 formed respectively in the dielectric layers Ly4 and Ly5.

The inductor pattern r4, forming a portion of the inductor L2b, is formed in the dielectric layer Ly4. The inductor pattern r4 is wound around a winding axis corresponding to the stacking direction and is formed to have approximately one turn wound in a clockwise direction in the drawing in the dielectric layer Ly4. One end of the inductor pattern r4 is electrically coupled to the electrode pattern r3 in the dielectric layer Ly3 through a via-conductor. The other end of the inductor pattern r4 is electrically coupled to an intermediate portion of the inductor pattern r5 in the dielectric layer Ly5 through a via-conductor. An intermediate portion of the inductor pattern r4 is electrically coupled to one end of the inductor pattern r5 in the dielectric layer Ly5 through a via-conductor.

The inductor pattern r5, forming a portion of the inductor L2b, is formed in the dielectric layer Ly5. The inductor pattern r5 is wound around a winding axis corresponding to the stacking direction and is formed to have approximately one turn wound in a clockwise direction in the drawing in the dielectric layer Ly5. The one end of the inductor pattern r5 is electrically coupled to the intermediate portion of the inductor pattern r4 in the dielectric layer Ly4 through a via-conductor. The other end of the inductor pattern r5 is electrically coupled to the inductor pattern r6 in the dielectric layer Ly6 through a via-conductor. The intermediate portion of the inductor pattern r5 is electrically coupled to the end of the inductor pattern r4 in the dielectric layer Ly4 through the via-conductor.

As described above, the inductor L2b is configured such that, when the insulating body 10 is viewed in the stacking direction, the inductor pattern r4 in the dielectric layer Ly4 and the inductor patterns r5 in the dielectric layer Ly5 are configured to have respective winding shapes that are wound around a winding axis corresponding to the stacking direction.

The inductor L2a is formed of inductor patterns r6, r8, and r10 formed respectively in the dielectric layers Ly6 to Ly8. The inductor L1b is formed of inductor patterns r7 and r9 formed respectively in the dielectric layers Ly6 and Ly7.

The inductor pattern r6, forming a portion of the inductor L2a, is formed in the dielectric layer Ly6. The inductor pattern r6 is electrically coupled to one end of the inductor pattern r5 in the dielectric layer Ly5 through a via-conductor. The inductor pattern r6 is also electrically coupled to one end of the inductor pattern r8 in the dielectric layer Ly7 through a via-conductor.

The inductor pattern r7, forming a portion of the inductor L1b, is formed in the dielectric layer Ly6. The inductor pattern r7 is wound around a winding axis corresponding to the stacking direction and is formed to have approximately one turn wound in a counterclockwise direction in the drawing in the dielectric layer Ly6. One end of the inductor pattern r7 is electrically coupled to the second port P2 (the outer electrode 12c of the second outer electrode 12). The other end of the inductor pattern r7 is electrically coupled to an intermediate portion of the inductor pattern r9 in the dielectric layer Ly7 through a via-conductor. An intermediate portion of the inductor pattern r7 is electrically coupled to one end of the inductor pattern r9 in the dielectric layer Ly7 through the via-conductor.

The inductor pattern r8, forming a portion of the inductor L2a, is formed in the dielectric layer Ly7. One end of the inductor pattern r8 is electrically coupled to the inductor pattern r6 in the dielectric layer Ly6 through a via-conductor. The other end of the inductor pattern r8 is electrically coupled to one end of the inductor pattern r10 in the dielectric layer Ly8 through a via-conductor.

The inductor pattern r9, forming a portion of the inductor L1b, is formed in the dielectric layer Ly7. The inductor pattern r9 is wound around a winding axis corresponding to the stacking direction and is formed to have approximately one turn wound in a counterclockwise direction in the drawing in the dielectric layer Ly7. The one end of the inductor pattern r9 is electrically coupled to the intermediate portion of the inductor pattern r7 in the dielectric layer Ly6 through a via-conductor. The other end of the inductor pattern r9 is electrically coupled to the first port P1 (the outer electrode 11c of the first outer electrode 11). The intermediate portion of the inductor pattern r9 is electrically coupled to the one end of the inductor pattern r7 in the dielectric layer Ly6 through the via-conductor.

As described above, the inductor L1b is configured such that, when the insulating body 10 is viewed in the stacking direction, the inductor pattern r7 in the dielectric layer Ly6 and the inductor patterns r9 in the dielectric layer Ly7 are configured to have respective winding shapes that are wound around a winding axis corresponding to the stacking direction.

The inductor pattern r10, forming a portion of the inductor L2a, is formed in the dielectric layer Ly8. The inductor pattern r10 is wound around a winding axis corresponding to the stacking direction and is formed to have approximately one turn wound in a clockwise direction in the drawing in the dielectric layer Ly8. The one end of the inductor pattern r10 is electrically coupled to the one end of the inductor pattern r8 in the dielectric layer Ly7 through the via-conductor. The other end of the inductor pattern r10 is electrically coupled to the second port P2 (the outer electrode 12c of the second outer electrode 12).

As described above, the inductor L2a is configured such that, when the insulating body 10 is viewed in the stacking direction, the inductor patterns r10 in the dielectric layer Ly8 is configured to have a winding shape that is wound around a winding axis corresponding to the stacking direction.

The inductor L1a is formed of inductor patterns r11 and r12 formed respectively in the dielectric layers Ly9 and Ly10.

The inductor pattern r11, forming a portion of the inductor L1a, is formed in the dielectric layer Ly9. The inductor pattern r11 is wound around a winding axis corresponding to the stacking direction and is formed to have approximately one turn wound in a counterclockwise direction in the drawing in the dielectric layer Ly9. One end of the inductor pattern r11 is electrically coupled to the second port P2 (the outer electrode 12c of the second outer electrode 12). The other end of the inductor pattern r11 is electrically coupled to an intermediate portion of the inductor pattern r12 in the dielectric layer Ly10 through a via-conductor. An intermediate portion of the inductor pattern r11 is electrically coupled to one end of the inductor pattern r12 in the dielectric layer Ly10 through a via-conductor.

The inductor pattern r12, forming a portion of the inductor L1a, is formed in the dielectric layer Ly10. The inductor pattern r12 is wound around a winding axis corresponding to the stacking direction and is formed to have approximately one turn wound in a counterclockwise direction in the drawing in the dielectric layer Ly10. The one end of the inductor pattern r12 is electrically coupled to the intermediate portion of the inductor pattern r11 in the dielectric layer Ly9 through a via-conductor. The other end of the inductor pattern r12 is electrically coupled to the first port P1 (the outer electrode 11c of the first outer electrode 11). The intermediate portion of the inductor pattern r12 is electrically coupled to the end of the inductor pattern r11 in the dielectric layer Ly9 through a via-conductor.

As described above, the inductor L1a is configured such that, when the insulating body 10 is viewed in the stacking direction, the inductor pattern r11 in the dielectric layer Ly9 and the inductor patterns r12 in the dielectric layer Ly10 are configured to have respective winding shapes that are wound around a winding axis corresponding to the stacking direction.

One end of the inductor pattern r7 in the dielectric layer Ly6, forming a portion of the inductor L1b, one end of the inductor pattern r10 in the dielectric layer Ly8, forming a portion of the inductor L2a, and one end of the inductor pattern r11 in the dielectric layer Ly9, forming a portion of the inductor L1a, are electrically coupled through the first port P1 (the outer electrode 11c of the first outer electrode 11). As such, the inductors L1a, L1b, and L2a are coupled at a common potential.

The electrode pattern r13 is formed in the dielectric layer Ly11. One end of the electrode pattern r13 is electrically coupled to the second port P2 (the outer electrode 12b of the second outer electrode 12), and the other end of the electrode pattern r13 is electrically coupled to the second port P2 (the outer electrode 12c of the second outer electrode 12). An intermediate portion of the electrode pattern r13 is electrically coupled to the electrode pattern r15 in the dielectric layer Ly12 through a via-conductor.

The electrode pattern r14 is also formed in the dielectric layer Ly11. One end of the electrode pattern r14 is electrically coupled to the first port P1 (the outer electrode 11b of the first outer electrode 11), and the other end of the electrode pattern r14 is electrically coupled to the first port P1 (the outer electrode 11c of the first outer electrode 11). An intermediate portion of the electrode pattern r14 is electrically coupled to the electrode pattern r16 in the dielectric layer Ly12 through a via-conductor.

The electrode pattern r15 is formed in the dielectric layer Ly12. The electrode pattern r15 is electrically coupled to the intermediate portion of the electrode pattern r13 in the dielectric layer Ly11 through the via-conductor. The electrode pattern r15 is also electrically coupled to the electrode pattern r17 in the dielectric layer Ly13 through a via-conductor.

The electrode pattern r16 is formed in the dielectric layer Ly12. The electrode pattern r16 is electrically coupled to the intermediate portion of the electrode pattern r14 in the dielectric layer Ly11 through the via-conductor. The electrode pattern r16 is also electrically coupled to the electrode pattern r18 in the dielectric layer Ly13 through a via-conductor.

The electrode pattern r17 is formed in the dielectric layer Ly13. The electrode pattern r17 is electrically coupled to the electrode pattern r15 in the dielectric layer Ly12 through the via-conductor. The electrode pattern r17 is also electrically coupled to the second port P2 (the outer electrode 12a of the second outer electrode 12) through a via-conductor.

The electrode pattern r18 is formed in the dielectric layer Ly13. The electrode pattern r18 is electrically coupled to the electrode pattern r16 in the dielectric layer Ly12 through the via-conductor. The electrode pattern r18 is also electrically coupled to the first port P1 (the outer electrode 11a of the first outer electrode 11) through a via-conductor.

In the filter device 100 configured as described above, the inductors L1a, L1b, L2a, and L2b are arranged to face each other in the stacking direction. When the insulating body 10 is viewed in the stacking direction, at least a portion of the openings of the inductors L1a and L1b overlap the openings of the inductors L2a and L2b. The larger the area in which the openings of the inductors L1a and L1b overlap the openings of the inductors L2a and L2b, the larger the coupling coefficient k between the inductor L1 (the inductors L1a and L1b) and the inductor L2 (the inductor L2a and L2b) becomes, resulting in greater mutual inductance due to magnetic coupling.

In the filter device 100, the inductors L1 and L2 are alternately disposed in the stacking direction and are magnetically coupled. Specifically, as illustrated in FIGS. 7 to 9, the inductors L1a and L1b included in the inductor L1 and the inductors L2a and L2b included in the inductor L2 are alternately disposed in the stacking direction.

For example, in the filter device 100, in order from the bottom surface at which the outer electrodes 11a and 12a are disposed to the top surface in the stacking direction, the inductor patterns r11 and r12 forming the inductor L1a (the inductor L1), the inductor pattern r10 forming the inductor L2a (the inductor L2), the inductor patterns r7 and r9 forming the inductor L1b (the inductor L1), and the inductor pattern r4 and r5 forming the inductor L2b (the inductor L2) are disposed.

In other words, the inductor pattern r10 forming the inductor L2a (the inductor L2) is sandwiched between the inductor patterns r11 and r12 forming the inductor L1a (the inductor L1) and the inductor patterns r7 and r9 forming the inductor L1b (the inductor L1) in the stacking direction. The inductor patterns r7 and r9 forming the inductor L1b (the inductor L1) are sandwiched between the inductor pattern r10 forming the inductor L2a (the inductor L2) and the inductor patterns r4 and r5 forming the inductor L2b (the inductor L2) in the stacking direction.

In the filter device 100 configured as described above, the coupling coefficient k between the inductor L1 (the inductors L1a and L1b) and the inductor L2 (the inductors L2a and L2b) can be increased by positioning the inductors L1a and L1b forming the inductor L1 and the inductors L2a and L2b forming the inductor L2 close together, without increasing the number of turns of the inductor L2 or increasing the opening area of the inductor L2. With this configuration, the filter device 100 according to the first embodiment effectively attenuates radio-frequency signals through parallel resonance to obtain favorable attenuation and bandpass characteristics, while achieving miniaturization.

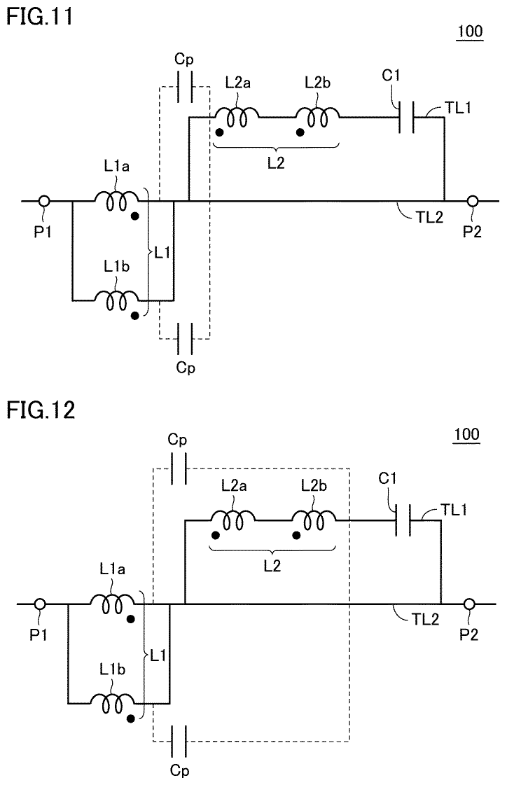

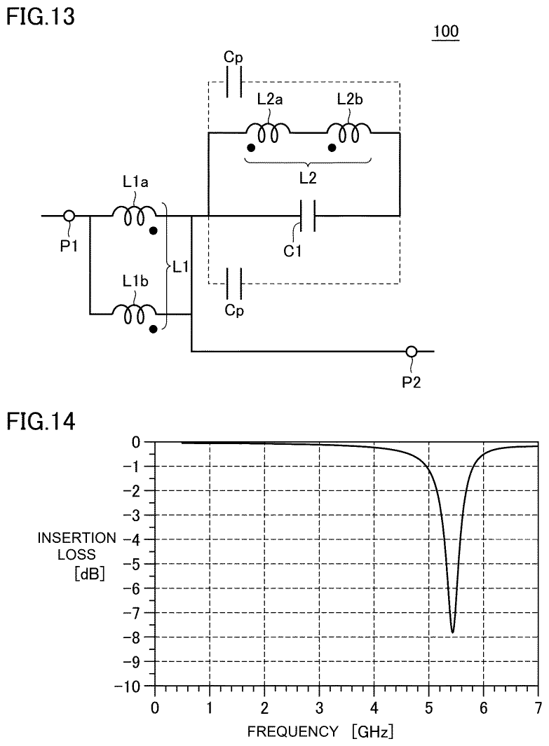

Next, with reference to FIGS. 11 to 13, the parasitic capacitance generated between the inductors L1 and L2 when the inductors L1 and L2 are positioned close together will be described. FIGS. 11 to 13 are detailed circuit diagrams illustrating the parasitic capacitance generated in the filter device 100 according to the first embodiment. FIG. 13 provides a circuit diagram obtained by modifying the circuit diagram illustrated in FIG. 12 for ease of viewing.

As illustrated in FIG. 11, a parasitic capacitance Cp can be generated between the inductors L1a and L2a when the inductors L1a and L2a are positioned close together. A parasitic capacitance Cp can be generated between the inductors L1a and L2a when the inductors L1b and L2a are positioned close together.

However, each of the inductors L1a and L1b is coupled in series with the inductor L2a at a common potential, and furthermore, the second path TL2 (short-circuited path) is coupled in parallel with the parasitic capacitance Cp described above. As a result, the filter device 100 is less susceptible to the effects of the parasitic capacitance Cp due to the presence of the second path TL2 (short-circuited path). Accordingly, the parasitic capacitance Cp between the inductors L1a and L2a can be considered negligible in the filter device 100.

As illustrated in FIGS. 12 and 13, a parasitic capacitance Cp can be generated between the inductors L1a and L2b when the inductors L1a and L2b are positioned close together. Since the inductors L1b and L2a are provided between the inductors L1a and L2b, the proximity between the inductors L1a and L2b is relatively low; however, a parasitic capacitance Cp can still be generated to some extent. A parasitic capacitance Cp can be generated between the inductors L1b and L2b when the inductors L1b and L2b are positioned close together.

However, the capacitor C1 of the resonant circuit RS is coupled in parallel with the parasitic capacitance Cp described above. Thus, in the filter device 100, the parasitic capacitance Cp can be used instead of the capacitor C1, or the parasitic capacitance Cp can be used as part of the capacitor C1. As described above, since the filter device 100 can use the parasitic capacitance Cp between the inductors L1a and L2b and the parasitic capacitance Cp between the inductors L1b and L2b as the capacitor C1, the size of the capacitor C1 can be reduced. As a result, as illustrated in FIGS. 7 to 10, when the insulating body 10 is viewed in the stacking direction, designers can position the electrode patterns forming the capacitor C1 to avoid the openings of the inductors L1a, L1b, L2a, and L2b within the limited space in the insulating body 10, thereby minimizing the influence of the capacitor C1 on the inductors L1a, L1b, L2a, and L2b.

As described above, the filter device 100 can avoid the occurrence of self-resonance in the inductor L1 or L2 due to the parasitic capacitance generated when the inductors L1 and L2 are positioned close together, thereby achieving a favorable bandpass characteristic.

FIG. 14 is a graph illustrating an example of insertion loss of the filter device 100 according to the first embodiment. In FIG. 14, the graph has the horizontal axis representing frequency and the vertical axis representing insertion loss, illustrating the frequency characteristic of insertion loss of the filter device 100.

As illustrated in FIG. 14, the filter device 100 is capable of attenuating radio-frequency signals sharply and greatly in the attenuation band through parallel resonance, and of passing radio-frequency signals in the pass band while minimizing attenuation of radio-frequency signals through series resonance.

As described above, the filter device 100 obtains favorable attenuation and bandpass characteristics while achieving miniaturization.

### Second Embodiment

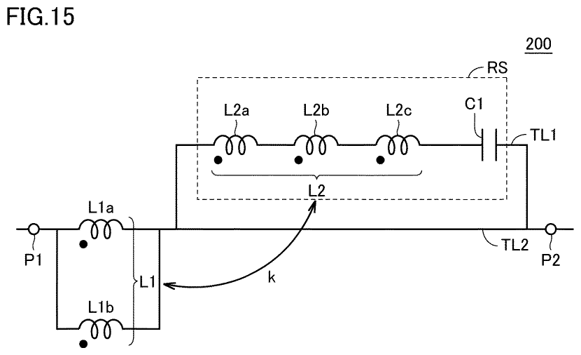

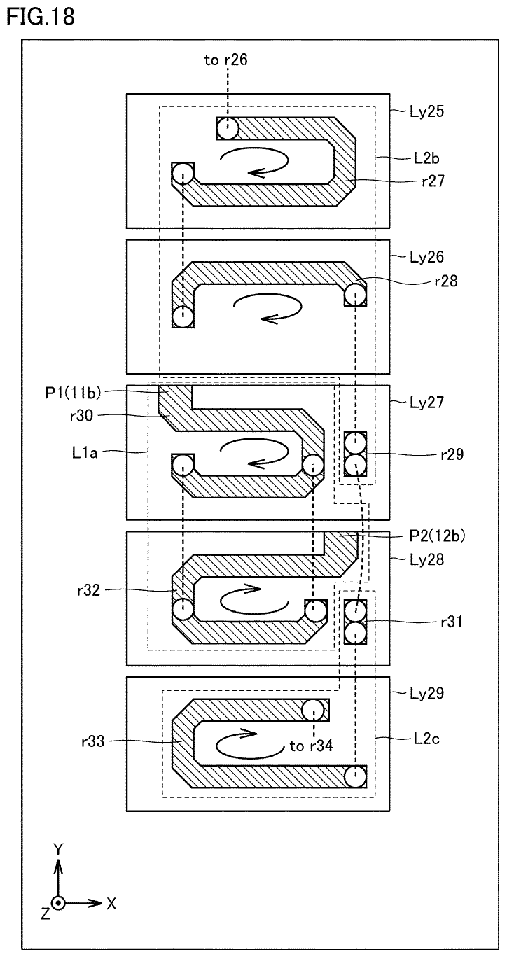

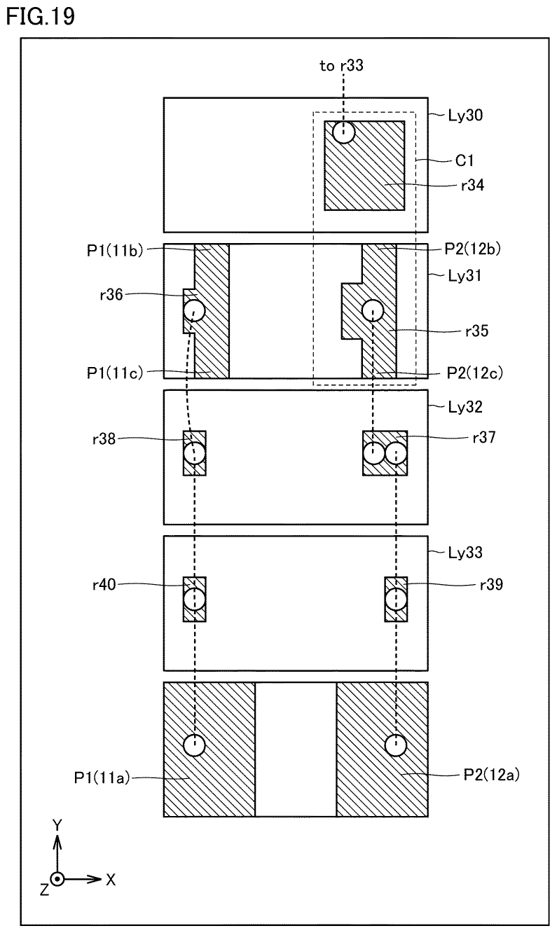

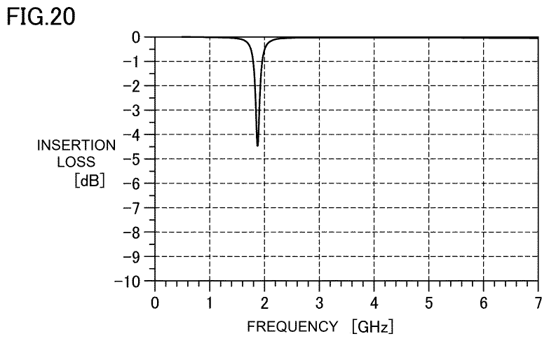

Referring to FIGS. 15 to 20, a filter device 200 according to a second embodiment will be described. In the following, only the features of the filter device 200 according to the second embodiment that are different from the features of the filter device 100 according to the first embodiment will be described.

FIG. 15 is a detailed circuit diagram of the filter device 200 according to the second embodiment. In the filter device 100 according to the first embodiment, the number of inductors (the inductors L1a and L1b) included in the inductor L1 and the number of inductors (the inductors L2a and L2b) included in the inductor L2 are the same. By contrast, in the filter device 200 according to the second embodiment, the number of inductors included in the inductor L2 is greater than the number of inductors included in the inductor L1.

Additionally, the filter device 200 according to the second embodiment is not limited to a configuration in which the inductors included in the inductor L1 and the inductors included in the inductor L2 are alternately stacked one by one, but may also have a configuration in which the inductors included in the inductor L1 and the inductors included in the inductor L2 are stacked alternately in groups of multiple inductors.

Specifically, as illustrated in FIG. 15, the filter device 200 includes, as an inductor L1, inductors L1a and L1b coupled in parallel between a first port P1 and a resonant circuit RS, and as an inductor L2, inductors L2a, L2b, and L2c coupled in series between the inductor L1 and a second port P2. The inductors L1a and L1b are examples of a “first sub-inductor,” and the inductors L2a, L2b, and L2c are examples of a “second sub-inductor.”

Of the inductors L2a, L2b, and L2c coupled in series, the inductor L2a is coupled to the inductors L1a and L1b, while the inductor L2c is coupled to a capacitor C1. In the example in FIG. 15, the inductors L1 and L2 are in additive coupling, resulting in a coupling coefficient k. The inductors L1 and L2 may be coupled in subtractive coupling.

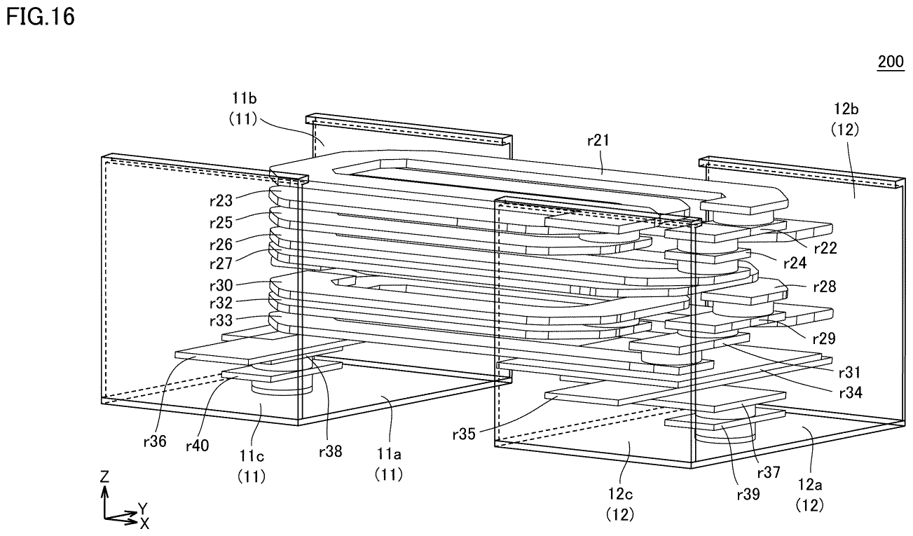

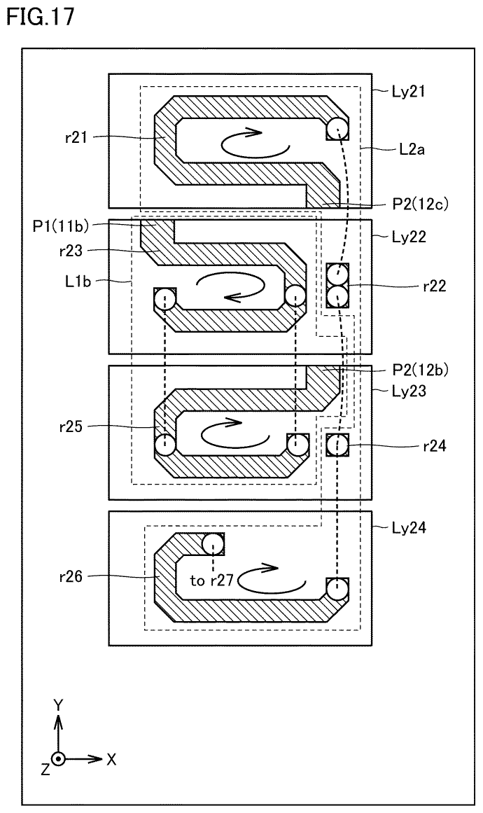

FIG. 16 is a perspective view illustrating the stacked structure of the filter device 200 according to the second embodiment. In FIG. 16, the outline of the insulating body 10 is omitted for ease of understanding the description of the filter device 200. FIGS. 17 to 19 provide exploded plan views illustrating the stacked structure of the filter device 200 according to the second embodiment.

As illustrated in FIGS. 16 to 19, the filter device 200 is formed by stacking multiple dielectric layers Ly21 to Ly33 in the stacking direction (Z direction) through a stacking process. The dielectric layers Ly21 to Ly33 are ceramic green sheets. The electrode patterns and inductor patterns are formed by applying a conductive paste (for example, Ni paste) using a screen-printing method.

The inductor L2a is formed of inductor patterns r21, r22, r24, and r26 formed respectively in the dielectric layers Ly21 to Ly24. The inductor L1b is formed of inductor patterns r23 and r25 formed respectively in the dielectric layers Ly22 and Ly23.

The inductor pattern r21, forming a portion of the inductor L2a, is formed in the dielectric layer Ly21. The inductor pattern r21 is wound around a winding axis corresponding to the stacking direction and is formed to have approximately one turn wound in a clockwise direction in the drawing in the dielectric layer Ly21. One end of the inductor pattern r21 is electrically coupled to the inductor pattern r22 in the dielectric layer Ly22 through a via-conductor. The other end of the inductor pattern r21 is electrically coupled to the second port P2 (the outer electrode 12c of the second outer electrode 12).

The inductor pattern r22, forming a portion of the inductor L2a, is formed in the dielectric layer Ly22. The inductor pattern r22 is electrically coupled to one end of the inductor pattern r21 in the dielectric layer Ly21 through a via-conductor. The inductor pattern r22 is also electrically coupled to the inductor pattern r24 in the dielectric layer Ly23 through a via-conductor.

The inductor pattern r23, forming a portion of the inductor L1b, is formed in the dielectric layer Ly22. The inductor pattern r23 is wound around a winding axis corresponding to the stacking direction and is formed to have approximately one turn wound in a clockwise direction in the drawing in the dielectric layer Ly22. One end of the inductor pattern r23 is electrically coupled to an intermediate portion of the inductor pattern r25 in the dielectric layer Ly23 through a via-conductor. The other end of the inductor pattern r23 is electrically coupled to the first port P1 (the outer electrode 11b of the first outer electrode 11). The intermediate portion of the inductor pattern r23 is electrically coupled to the end of the inductor pattern r25 in the dielectric layer Ly23 through a via-conductor.

The inductor pattern r24, forming a portion of the inductor L2a, is formed in the dielectric layer Ly23. The inductor pattern r24 is also electrically coupled to the inductor pattern r22 in the dielectric layer Ly22 through a via-conductor. The inductor pattern r24 is also electrically coupled to one end of the inductor pattern r26 in the dielectric layer Ly24 through a via-conductor.

The inductor pattern r25, forming a portion of the inductor L1b, is formed in the dielectric layer Ly23. The inductor pattern r25 is wound around a winding axis corresponding to the stacking direction and is formed to have approximately one turn wound in a clockwise direction in the drawing in the dielectric layer Ly23. One end of the inductor pattern r25 is electrically coupled to the second port P2 (the outer electrode 12b of the second outer electrode 12). The other end of the inductor pattern r25 is electrically coupled to an intermediate portion of the inductor pattern r23 in the dielectric layer Ly22 through a via-conductor. The intermediate portion of the inductor pattern r25 is electrically coupled to the end of the inductor pattern r23 in the dielectric layer Ly22 through a via-conductor.

The inductor pattern r26, forming a portion of the inductor L2a, is formed in the dielectric layer Ly24. The inductor pattern r26 is wound around a winding axis corresponding to the stacking direction and is formed to have approximately a half turn wound in a clockwise direction in the drawing in the dielectric layer Ly24. One end of the inductor pattern r26 is electrically coupled to one end of the inductor pattern r27 in the dielectric layer Ly25 through a via-conductor. The other end of the inductor pattern r26 is electrically coupled to the inductor pattern r24 in the dielectric layer Ly23 through a via-conductor.

As described above, the inductor L2a is configured such that, when the insulating body 10 is viewed in the stacking direction, the inductor pattern r21 in the dielectric layer Ly21 and the inductor patterns r26 in the dielectric layer Ly24 are configured to have respective winding shapes that are wound around a winding axis corresponding to the stacking direction. As described above, the inductor L1b is configured such that, when the insulating body 10 is viewed in the stacking direction, the inductor pattern r23 in the dielectric layer Ly22 and the inductor patterns r25 in the dielectric layer Ly23 are configured to have respective winding shapes that are wound around a winding axis corresponding to the stacking direction.

The inductor L2b is formed of inductor patterns r27 and r28 formed respectively in the dielectric layers Ly25 and Ly26.

The inductor pattern r27, forming a portion of the inductor L2b, is formed in the dielectric layer Ly25. The inductor pattern r27 is wound around a winding axis corresponding to the stacking direction and is formed to have approximately one turn wound in a clockwise direction in the drawing in the dielectric layer Ly25. One end of the inductor pattern r27 is electrically coupled to one end of the inductor pattern r28 in the dielectric layer Ly26 through a via-conductor. The other end of the inductor pattern r27 is electrically coupled to one end of the inductor pattern r26 in the dielectric layer Ly24 through a via-conductor.

The inductor pattern r28, forming a portion of the inductor L2b, is formed in the dielectric layer Ly26. The inductor pattern r28 is wound around a winding axis corresponding to the stacking direction and is formed to have approximately a half turn wound in a clockwise direction in the drawing in the dielectric layer Ly26. The one end of the inductor pattern r28 is electrically coupled to the one end of the inductor pattern r27 in the dielectric layer Ly25 through the via-conductor. The other end of the inductor pattern r28 is electrically coupled to the inductor pattern r29 in the dielectric layer Ly27 through a via-conductor.

As described above, the inductor L2b is configured such that, when the insulating body 10 is viewed in the stacking direction, the inductor pattern r27 in the dielectric layer Ly25 and the inductor patterns r28 in the dielectric layer Ly26 are configured to have respective winding shapes that are wound around a winding axis corresponding to the stacking direction.

The inductor L1a is formed of inductor patterns r30 and r32 formed respectively in the dielectric layers Ly27 and Ly28.

The inductor pattern r29, forming a portion of the inductor L2b, is formed in the dielectric layer Ly27. The one end of the inductor pattern r29 is electrically coupled to the end of the inductor pattern r28 in the dielectric layer Ly26 through the via-conductor. The other end of the inductor pattern r29 is electrically coupled to one end of the inductor pattern r31 in the dielectric layer Ly28 through a via-conductor.

The inductor pattern r30, forming a portion of the inductor L1a, is formed in the dielectric layer Ly27. The inductor pattern r30 is wound around a winding axis corresponding to the stacking direction and is formed to have approximately one turn wound in a clockwise direction in the drawing in the dielectric layer Ly27. One end of the inductor pattern r30 is electrically coupled to an intermediate portion of the inductor pattern r32 in the dielectric layer Ly28 through a via-conductor. The other end of the inductor pattern r30 is electrically coupled to the first port P1 (the outer electrode 11b of the first outer electrode 11). An intermediate portion of the inductor pattern r30 is electrically coupled to the end of the inductor pattern r32 in the dielectric layer Ly28 through a via-conductor.

The inductor pattern r31, forming a portion of the inductor L2c, is formed in the dielectric layer Ly28. One end of the inductor pattern r31 is electrically coupled to one end of the inductor pattern r29 in the dielectric layer Ly27 through a via-conductor. The other end of the inductor pattern r31 is electrically coupled to one end of the inductor pattern r33 in the dielectric layer Ly29 through a via-conductor.

The inductor pattern r32, forming a portion of the inductor L1a, is formed in the dielectric layer Ly28. The inductor pattern r32 is wound around a winding axis corresponding to the stacking direction and is formed to have approximately one turn wound in a clockwise direction in the drawing in the dielectric layer Ly28. One end of the inductor pattern r32 is electrically coupled to the second port P2 (the outer electrode 12b of the second outer electrode 12). The other end of the inductor pattern r32 is electrically coupled to the intermediate portion of the inductor pattern r30 in the dielectric layer Ly27 through a via-conductor. The intermediate portion of the inductor pattern r32 is electrically coupled to the end of the inductor pattern r30 in the dielectric layer Ly27 through the via-conductor.

As described above, the inductor L1a is configured such that, when the insulating body 10 is viewed in the stacking direction, the inductor pattern r30 in the dielectric layer Ly27 and the inductor patterns r32 in the dielectric layer Ly28 are configured to have respective winding shapes that are wound around a winding axis corresponding to the stacking direction.

The inductor L2c is formed of an inductor pattern r33 formed in the dielectric layer Ly29.

The inductor pattern r33, forming the inductor L2c, is formed in the dielectric layer Ly29. The inductor pattern r33 is wound around a winding axis corresponding to the stacking direction and is formed to have approximately one turn wound in a clockwise direction in the drawing in the dielectric layer Ly29. One end of the inductor pattern r33 is electrically coupled to the inductor pattern r34 in the dielectric layer Ly30 through a via-conductor. The other end of the inductor pattern r33 is electrically coupled to the inductor pattern r31 in the dielectric layer Ly28 through a via-conductor.

As described above, the inductor L2c is configured such that, when the insulating body 10 is viewed in the stacking direction, the inductor pattern r33 in the dielectric layer Ly29 is configured to have a winding shape that is wound around a winding axis corresponding to the stacking direction.

The capacitor C1 is formed of electrode patterns r34 and r35 formed respectively in the dielectric layers Ly30 and Ly31.

The electrode pattern r34, forming a portion of the capacitor C1, is formed in the dielectric layer Ly30. The electrode pattern r34 is electrically coupled to one end of the inductor pattern r33 in the dielectric layer Ly29 through a via-conductor.

The electrode pattern r35, forming a portion of the capacitor C1, is formed in the dielectric layer Ly31. One end of the electrode pattern r35 is electrically coupled to the second port P2 (the outer electrode 12b of the second outer electrode 12). The other end of the electrode pattern r35 is electrically coupled to the second port P2 (the outer electrode 12c of the second outer electrode 12). An intermediate portion of the inductor pattern r35 is electrically coupled to the electrode pattern r37 in the dielectric layer Ly32 through a via-conductor.

The electrode pattern r36 is formed in the dielectric layer Ly31. One end of the electrode pattern r36 is electrically coupled to the first port P1 (the outer electrode 11b of the first outer electrode 11). The other end of the electrode pattern r36 is electrically coupled to the first port P1 (the outer electrode 11c of the first outer electrode 11). An intermediate portion of the inductor pattern r36 is electrically coupled to the electrode pattern r38 in the dielectric layer Ly32 through a via-conductor.

As described above, the capacitor C1 is formed by using the space formed between the electrode pattern r34 formed in the dielectric layer Ly30 and the electrode pattern r35 formed in the dielectric layer Ly31.

The electrode pattern r37 is formed in the dielectric layer Ly32. The electrode pattern r37 is electrically coupled to the intermediate portion of the electrode pattern r35 in the dielectric layer Ly31 through the via-conductor. The electrode pattern r37 is also electrically coupled to the electrode pattern r39 in the dielectric layer Ly33 through a via-conductor.

The electrode pattern r38 is formed in the dielectric layer Ly32. The electrode pattern r38 is electrically coupled to the intermediate portion of the electrode pattern r36 in the dielectric layer Ly31 through the via-conductor. The electrode pattern r38 is also electrically coupled to the electrode pattern r40 in the dielectric layer Ly33 through a via-conductor.

The electrode pattern r39 is formed in the dielectric layer Ly33. The electrode pattern r39 is electrically coupled to the electrode pattern r37 in the dielectric layer Ly32 through the via-conductor. The electrode pattern r39 is also electrically coupled to the second port P2 (the outer electrode 12a of the second outer electrode 12) through a via-conductor.

The electrode pattern r40 is formed in the dielectric layer Ly33. The electrode pattern r40 is electrically coupled to the electrode pattern r38 in the dielectric layer Ly32 through the via-conductor. The electrode pattern r40 is also electrically coupled to the first port P1 (the outer electrode 11a of the first outer electrode 11) through a via-conductor.

In the filter device 200 configured as described above, the inductors L1a, L1b, L2a, L2b, and L2c are arranged to face each other in the stacking direction. When the insulating body 10 is viewed in the stacking direction, at least a portion of the openings of the inductors L1a and L1b overlap the openings of the inductors L2a, L2b, and L2c. The larger the area in which the openings of the inductors L1a and L1b overlap the openings of the inductors L2a, L2b, and L2c, the larger the coupling coefficient k between the inductor L1 (the inductors L1a and L1b) and the inductor L2 (the inductor L2a, L2b, and L2c) becomes, resulting in greater mutual inductance due to magnetic coupling.

In the filter device 200, the inductors L1 and L2 are alternately disposed in the stacking direction and are magnetically coupled. Specifically, as illustrated in FIGS. 16 to 19, the inductors L1a and L1b included in the inductor L1 and the inductors L2a, L2b, and L2c included in the inductor L2 are alternately disposed in the stacking direction.

For example, in the filter device 200, in order from the bottom surface at which the outer electrodes 11a and 12a are disposed to the top surface in the stacking direction, the inductor pattern r33 forming the inductor L2c (the inductor L2), the inductor patterns r30 and r32 forming the inductor L1a (the inductor L1), the inductor patterns r27 and r28 forming the inductor L2b (the inductor L2), the inductor pattern r26 forming the inductor L2a (the inductor L2), the inductor patterns r23 and r25 forming the inductor L1b (the inductor L1), and the inductor pattern r21 forming the inductor L2a (the inductor L2) are disposed.

In other words, the inductor patterns r23 and r25 forming the inductor L1b (the inductor L1) are sandwiched between the inductor pattern r21 forming the inductor L2a (the inductor L2) and the inductor pattern r26 forming the inductor L2a (the inductor L2) in the stacking direction. The inductor pattern r26 forming the inductor L2a (the inductor L2) and the inductor patterns r27 and r28 forming the inductor L2b (the inductor L2) are sandwiched between the inductor patterns r23 and r25 forming the inductor L1b (the inductor L1) and the inductor patterns r30 and r32 forming the inductors L1a (the inductor L1) in the stacking direction. The inductor patterns r30 and r32 forming the inductor L1a (the inductor L1) are sandwiched between the inductor patterns r27 and r28 forming the inductor L2b (the inductor L2) and the inductor pattern r33 forming the inductor L2c (the inductor L2).

As described above, in the filter device 200, the number of inductors included in the inductor L2 is greater than the number of inductors included in the inductor L1. In the filter device 200, multiple inductors L2 (the inductors L2a and L2b) are sandwiched between two inductors L1 (the inductors L1b and L1a) in the stacking direction.

In the filter device 200 configured as described above, the coupling coefficient k between the inductor L1 (the inductors L1a and L1b) and the inductor L2 (the inductors L2a, L2b, and L2c) can be increased by positioning the inductors L1a and L1b forming the inductor L1 and the inductors L2a, L2b, and L2c forming the inductor L2 close together, without increasing the number of turns of the inductor L2 or increasing the opening area of the inductor L2. With this configuration, the filter device 200 effectively attenuates radio-frequency signals through parallel resonance to obtain favorable attenuation and bandpass characteristics, while achieving miniaturization.

Further, similarly to the filter device 100 according to the first embodiment, the parasitic capacitance Cp between the inductors L1a and L2a can be considered negligible in the filter device 200. Additionally, the parasitic capacitance Cp between the inductors L1a and each of the inductors L2b and L2c can be used as the capacitor C1 in the filter device 200. Thus, the filter device 200 can avoid the occurrence of self-resonance in the inductor L1 or L2 due to the parasitic capacitance generated when the inductors L1 and L2 are positioned close together, thereby achieving a favorable bandpass characteristic.

### Modifications

The present disclosure is not limited to the above-described embodiments, and various modifications and applications are possible. The following describes modifications that are applicable to the present disclosure.

The number of inductors included in the inductor L1 may be one or more, and the number of inductors included in inductor L2 may also be one or more. In the filter device of the present disclosure, at least one of the inductors L1 and L2 may include multiple inductors, and the inductors L1 and L2 may be alternately disposed in the stacking direction and magnetically coupled.

For example, the filter device may include a single inductor L1 and multiple inductors L2, and each inductor may be disposed such that the single inductor L1 is sandwiched between the inductors L2 in the stacking direction.

For example, the filter device may include multiple inductors L1 and a single inductor L2, and each inductor may be disposed such that the single inductor L2 is sandwiched between the inductors L1 in the stacking direction.

For example, the filter device may include multiple inductors L1 and multiple inductors L2, and one of the inductors L1 and one of the inductors L2 may be alternately disposed in the stacking direction. Alternatively, each inductor may be disposed such that multiple inductors L2 are sandwiched between multiple inductors L1 in the stacking direction. Alternatively, each inductor may be disposed such that multiple inductors L1 are sandwiched between multiple inductors L2 in the stacking direction.

### Aspects

(Clause 1) A filter device (100, 200) according to an aspect, comprising: an insulating body (10) including a first outer electrode (11) and a second outer electrode (12), a first inductor (L1) coupled to the first outer electrode, and a resonant circuit (RS) including a second inductor (L2) and a capacitor (C1), wherein the first inductor is coupled to the second outer electrode and to the resonant circuit, the first inductor and the second inductor are stacked in the insulating body, at least one of the first inductor and the second inductor includes a plurality of inductor patterns, and the first inductor and the second inductor are alternately disposed in a stacking direction and are magnetically coupled.
(Clause 2) The filter device according to clause 1, wherein the filter device is a two-port filter having two ports formed by the first outer electrode and the second outer electrode, the filter device being configured to pass a radio-frequency signal within a first frequency band and to attenuate a radio-frequency signal within a second frequency band that is lower than the first frequency band.
(Clause 3) The filter device according to clause 1 or 2, wherein the second inductor and the capacitor are coupled in series between the first inductor and the second outer electrode.
(Clause 4) The filter device according to any one of clauses 1 to 3, wherein the first inductor and the second inductor are coupled in series between the first outer electrode and the second outer electrode.
(Clause 5) The filter device according to any one of clauses 1 to 4, wherein the first inductor includes a plurality of first sub-inductors (L1a, L1b) coupled in parallel between the first outer electrode and the resonant circuit.
(Clause 6) The filter device according to any one of clauses 1 to 5, wherein the second inductor includes a plurality of second sub-inductors (L2a, L2b, L2c) coupled in series between the first inductor and the second outer electrode.
(Clause 7) The filter device according to any one of clauses 1 to 6, wherein the first inductor includes a plurality of first sub-inductors (L1a, L1b), the second inductor includes at least one second sub-inductor (L2a), and the at least one second sub-inductor is sandwiched between the first sub-inductors in the stacking direction.
(Clause 8) The filter device according to any one of clauses 1 to 7, wherein the first inductor includes a plurality of first sub-inductors (L1a, L1b), the second inductor includes a plurality of second sub-inductors (L2a, L2b), the first sub-inductors and the second sub-inductors are alternately disposed in the stacking direction.
(Clause 9) The filter device according to any one of clauses 1 to 8, wherein the first sub-inductors are coupled in parallel between the first outer electrode and the resonant circuit, the second sub-inductors are coupled in series between the first inductor and the second outer electrode, and each of the first sub-inductors and a second sub-inductor of the second sub-inductors are coupled in series at a common potential.
(Clause 10) The filter device according to any one of clauses 1 to 9, wherein the first inductor is wound around a winding axis corresponding to the stacking direction, the second inductor is wound around a winding axis corresponding to the stacking direction, and at least a portion of an opening of the first inductor overlaps an opening of the second inductor when the insulating body is viewed in the stacking direction.
(Clause 11) The filter device according to any one of clauses 1 to 10, wherein second sub-inductors (L2a, L2b, L2c) included in the second inductor are greater in number than first sub-inductors (L1a, L1b) included in the first inductor.
(Clause 12) An antenna device (1) according to an aspect, comprising: a radiating element (50) configured to emit a radio-frequency signal within the first frequency band as radio waves, a feed circuit (RF1) configured to supply the radio-frequency signal within the first frequency band to the radiating element, and the filter device (100, 200) provided between the radiating element and the feed circuit.
(Clause 13) An antenna module (3) according to an aspect, comprising: a first antenna device (1) configured to emit a radio-frequency signal within the first frequency band as radio waves, and a second antenna device (2) configured to emit a radio-frequency signal within the second frequency band as radio waves, wherein the first antenna device is the antenna device (1) according to clause 12.

The embodiments disclosed herein should be considered as examples in all respects and should not be interpreted as limiting. The scope of the present disclosure is indicated by the claims rather than the above descriptions of the embodiments, and all changes that come within the meaning and range of equivalency of the claims are therefore intended to be embraced therein.

### REFERENCE SIGNS LIST

1, 2 antenna device, 3 antenna module, 10 insulating body, 11 first outer electrode, 11a, 11b, 11c, 12a, 12b, 12c outer electrode, 12 second outer electrode, 50, 60 radiating element, 70 substrate, 100, 200 filter device, C1 capacitor, Cp parasitic capacitance, L1a, L1b, L1, L2a, L2b, L2c, L2 inductor, P1 first port, P2 second port, RF1, RF2 feed circuit, RS resonant circuit, TL1 first path, TL2 second path.

1. A filter device comprising:
an insulating body including a first outer electrode and a second outer electrode;
a first inductor electrically coupled to the first outer electrode; and
a resonant circuit including a second inductor and a capacitor, wherein
the first inductor is electrically coupled to the second outer electrode and to the resonant circuit,
the first inductor and the second inductor are stacked in the insulating body,
at least one of the first inductor and the second inductor includes a plurality of inductor patterns, and
the first inductor and the second inductor are alternately disposed in a stacking direction and are magnetically coupled.

2. The filter device according to claim 1, wherein
the filter device is a two-port filter having two ports formed by the first outer electrode and the second outer electrode, the filter device being configured to pass a radio-frequency signal within a first frequency band and to attenuate a radio-frequency signal within a second frequency band that is lower than the first frequency band.

3. The filter device according to claim 1, wherein
the second inductor and the capacitor are electrically coupled in series between the first inductor and the second outer electrode.

4. The filter device according to claim 1, wherein
the first inductor and the second inductor are electrically coupled in series between the first outer electrode and the second outer electrode.

5. The filter device according to claim 1, wherein
the first inductor includes a plurality of first sub-inductors electrically coupled in parallel between the first outer electrode and the resonant circuit.

6. The filter device according to claim 1, wherein
the second inductor includes a plurality of second sub-inductors electrically coupled in series between the first inductor and the second outer electrode.

7. The filter device according to claim 1, wherein
the first inductor includes a plurality of first sub-inductors,
the second inductor includes at least one second sub-inductor, and
the at least one second sub-inductor is sandwiched between the first sub-inductors in the stacking direction.

8. The filter device according to claim 1, wherein
the first inductor includes a plurality of first sub-inductors,
the second inductor includes a plurality of second sub-inductors,
the first sub-inductors and the second sub-inductors are alternately disposed in the stacking direction.

9. The filter device according to claim 8, wherein
the first sub-inductors are electrically coupled in parallel between the first outer electrode and the resonant circuit,
the second sub-inductors are electrically coupled in series between the first inductor and the second outer electrode, and
each of the first sub-inductors and a second sub-inductor of the second sub-inductors are coupled in series at a common potential.

10. The filter device according to claim 1, wherein
the first inductor is wound around a winding axis corresponding to the stacking direction,
the second inductor is wound around a winding axis corresponding to the stacking direction, and
at least a portion of an opening of the first inductor overlaps an opening of the second inductor when the insulating body is viewed in the stacking direction.

11. The filter device according to claim 1, wherein
second sub-inductors included in the second inductor are greater in number than first sub-inductors included in the first inductor.

12. The filter device according to claim 1, wherein the capacitor includes an electrode pattern positioned that does not overlap an opening of the first inductor and an opening of the second inductor in the stacking direction.

13. The filter device according to claim 1, wherein the first inductor and the second inductor are magnetically coupled with additive polarity.

14. The filter device according to claim 1, wherein the first inductor and the second inductor are magnetically coupled with subtractive polarity.

15. The filter device according to claim 1, wherein the insulating body includes a mounting surface, and the stacking direction is perpendicular to the mounting surface.

16. The filter device according to claim 1, wherein the capacitor includes a plurality of capacitor electrode patterns disposed in dielectric layers of the insulating body that are different from dielectric layers containing the first inductor and the second inductor.

17. An antenna device comprising:
a radiating element configured to emit a radio-frequency signal within the first frequency band as radio waves;
a feed circuit configured to supply the radio-frequency signal within the first frequency band to the radiating element; and
the filter device according to claim 2, the filter device being provided between the radiating element and the feed circuit.

18. An antenna module comprising:
a first antenna device configured to emit a radio-frequency signal within the first frequency band as radio waves; and
a second antenna device configured to emit a radio-frequency signal within the second frequency band as radio waves, wherein
the first antenna device is the antenna device according to claim 16.

19. The antenna module according to claim 18, wherein the radiating element of the first antenna device and a radiating element of the second antenna device are on a common substrate.
